(19) United States
(12) Patent Application Publication
(10) Pub. No.: US 2026/0087222 A1
(43) Pub. Date: Mar. 26, 2026

(54) CONFIGURATION OF AN ADAPTIVE SYSTEM-ON-CHIP

(71) Applicant: Xilinx, Inc., San Jose, CA (US)

(72) Inventors: Stephen L. Bade, Lindon, UT (US); Felix Klas Burton, Foster City, CA (US); Izhar Ameer Shaikh, San Jose, CA (US); Tomas Evensen, Los Altos Hills, CA (US); Kalyani Tummala, Milpitas, CA (US); Thien C. Than, Thornton, CO (US)

(73) Assignee: Xilinx, Inc., San Jose, CA (US)

(21) Appl. No.: 18/897,727

(22) Filed: Sep. 26, 2024

(51) Int. Cl. G06F 30/392; G06F 30/394

(52) U.S. Cl. CPC G06F 30/392; G06F 30/394

(57) ABSTRACT

Configuring a System-on-Chip (SoC) can include receiving first configuration data for an SoC. The SoC has a plurality of hardware systems including programmable logic. The first configuration data includes a portion specifying a circuit design for the programmable logic. A user input specifying a change to a non-netlist configuration setting of the SoC can be received. Second configuration data for the SoC can be generated. The second configuration data specifies the change to the non-netlist configuration setting. Updated configuration data for the SoC can be generated by merging the second configuration data with the first configuration data leaving the portion of the first configuration data specifying the circuit design unchanged.

### TECHNICAL FIELD

This disclosure relates to integrated circuits (ICs) and, more particularly, to configuring an IC such as an adaptive System-on-Chip.

### BACKGROUND

System-on-Chips (SoCs) include a variety of different systems that are capable of operating in a cooperative manner. As an example, an SoC may include a system including programmable logic and one or more other or different systems. Configuring the SoC for operation involves a lengthy and complex workflow in which configuration data is generated from a user design. The configuration data may be loaded into the SoC to physically realize the user design in the SoC. The workflow to create configuration data entails processing a hardware description such as a netlist through an implementation flow that involves operations such as synthesis, placement, and routing. The netlist defines the circuitry to be implemented in the programmable logic system of the SoC. The workflow also generates configuration data for the other systems of the SoC.

In cases where a change to the configuration of the SoC is desired, the entire workflow must be performed anew including the implementation flow for the netlist. As may be appreciated, the implementation flow is a time consuming and complex process. Successfully navigating through an implementation flow often requires significant hardware design experience. This requirement leaves many users such as software developers that may lack hardware design experience unable to make desired changes in the configuration of the SoC despite the fact that many aspects of the configuration are highly relevant to the software development process. In many cases, the desired changes have little or no relation to the netlist implementation for the programmable logic of the SoC.

### SUMMARY

In one or more embodiments, a method includes receiving, by computer hardware, first configuration data for a System-on-Chip (SoC). The SoC has a plurality of hardware systems including programmable logic. The first configuration data includes a portion specifying a circuit design for the programmable logic. The method includes receiving, by the computer hardware, a user input specifying a change to a non-netlist configuration setting of the SoC. The method includes generating, by the computer hardware, second configuration data for the SoC. The second configuration data specifies the change to the non-netlist configuration setting. The method includes generating, by the computer hardware, updated configuration data for the SoC by merging the second configuration data with the first configuration data leaving the portion of the first configuration data specifying the circuit design unchanged.

In one or more embodiments, a system includes a memory capable of storing computer-readable program instructions. The system includes a hardware processor capable of executing the computer-readable program instructions to perform operations. The operations include receiving first configuration data for an SoC. The SoC has a plurality of hardware systems including programmable logic. The first configuration data includes a portion specifying a circuit design for the programmable logic. The operations include receiving a user input specifying a change to a non-netlist configuration setting of the SoC. The operations include generating second configuration data for the SoC. The second configuration data specifies the change to the non-netlist configuration setting. The operations include generating updated configuration data for the SoC by merging the second configuration data with the first configuration data leaving the portion of the first configuration data specifying the circuit design unchanged.

In one or more embodiments, a computer program product includes a computer readable storage medium having program instructions embodied therewith. The program instructions are executable by computer hardware to cause the computer hardware to perform operations. The operations include receiving first configuration data for an SoC. The SoC has a plurality of hardware systems including programmable logic. The first configuration data includes a portion specifying a circuit design for the programmable logic. The operations include receiving a user input specifying a change to a non-netlist configuration setting of the SoC. The operations include generating second configuration data for the SoC. The second configuration data specifies the change to the non-netlist configuration setting. The operations include generating updated configuration data for the SoC by merging the second configuration data with the first configuration data leaving the portion of the first configuration data specifying the circuit design unchanged.

This Summary section is provided merely to introduce certain concepts and not to identify any key or essential features of the claimed subject matter. Many other features and embodiments of the disclosed technology will be apparent from the accompanying drawings and from the following detailed description.

### BRIEF DESCRIPTION OF THE DRAWINGS

The accompanying drawings show one or more embodiments of the disclosed technology. The drawings, however, should not be construed to limit the embodiments to only those shown. Various aspects and advantages will become apparent upon review of the following detailed description and upon reference to the drawings.

FIG. 1 illustrates a System-on-Chip in accordance with one or more embodiments of the disclosed technology.

FIG. 2 illustrates an executable software architecture in accordance with one or more embodiments of the disclosed technology.

FIG. 3 illustrates a method of operation for the software architecture of FIG. 2 in accordance with one or more embodiments of the disclosed technology.

FIG. 4 illustrates a user interface of a configuration utility in accordance with one or more embodiments of the disclosed technology.

FIG. 5 illustrates another user interface of the configuration utility in accordance with one or more embodiments of the disclosed technology.

FIG. 6 illustrates an example implementation of a data processing system for use with the inventive arrangements described herein.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to integrated circuits (ICs) and, more particularly, to configuring an IC such as an adaptive System-on-Chip (SoC). Conventional Electronic Design Automation (EDA) tools capable of configuring an SoC that includes programmable logic utilize a workflow that generates configuration data for the entire SoC. That is, the workflow generates configuration data for the programmable logic system as well as other hardware systems of the SoC. Any changes to the configuration of the SoC require the EDA tool to perform the entire workflow anew.

Because the workflow generates configuration data for the programmable logic as well as the other hardware systems of the SoC, an implementation flow that is performed as part of the workflow to process a hardware description of circuitry to be implemented in the programmable logic is necessarily performed again. That is, the hardware description is again processed through an implementation flow involving synthesis, placement, routing, and the like. Such is the case even when the desired change to the configuration of the SoC is unrelated to the hardware description (e.g., the netlist). The EDA tool effectively re-processes the hardware description through the implementation flow, which is time consuming and requires hardware design experience.

In accordance with the inventive arrangements described within this disclosure, methods, systems, and computer program products are provided that are capable of changing one or more configuration settings of an SoC without having to perform an implementation flow on the hardware description. Changes to non-netlist configuration settings of the SoC may be effectuated through a utility or tool capable of implementing a process that omits the implementation flow. As defined within this disclosure, the term “non-netlist setting” or “non-netlist configuration setting” means a configuration setting of an SoC that has no impact on an implementation of a netlist within the programmable logic system of the SoC. That is, a change to the non-netlist configuration setting has no impact or effect on the implementation of a netlist in the programmable logic of the SoC.

As such, the utility is capable of effectuating the change to the non-netlist configuration setting of the SoC without changing or otherwise disturbing the configuration data previously generated that implements the netlist in the programmable logic of the SoC as one or more soft circuit blocks. Because the physical realization of the netlist in the programmable logic is not changed, the implementation flow is omitted from the workflow performed by the utility. This means that the workflow executed by the utility may be performed in significantly less time than is the case for a conventional EDA tool. Further, a designer lacking hardware design experience is able to make desired changes to non-netlist settings of the SoC because the existing configuration data for the programmable logic is left unchanged.

Further aspects of the inventive arrangements are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

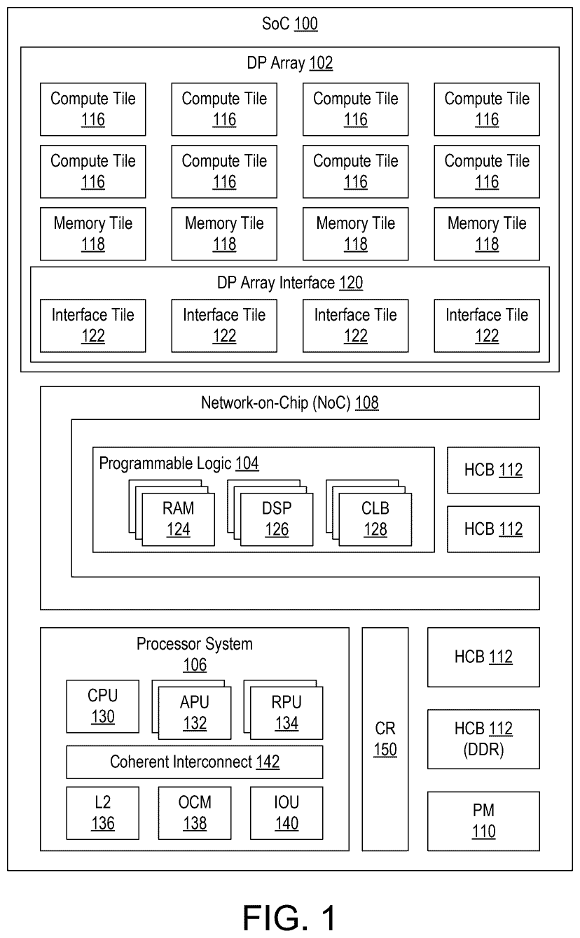

FIG. 1 illustrates an SoC 100 in accordance with one or more embodiments of the disclosed technology. SoC 100 may be implemented as any of a variety of different types of ICs including, but not limited to programmable SoCs and/or adaptive SoCs. In the example of FIG. 1, SoC 100 is implemented on a single die provided within a single package. In other examples, SoC 100 may be implemented using a plurality of interconnected dies within a single package where the various hardware systems of SoC 100 (e.g., circuits) illustrated in FIG. 1 are implemented across the different interconnected dies. The term “die” may also refer to a “chiplet.”

In the example, SoC 100 includes a plurality of different hardware systems including a data processing (DP) array 102, programmable logic 104, a processor system (PS) 106, a Network-on-Chip (NoC) 108, a platform manager 110, and various other systems illustrated as hardwired circuit blocks (HCBs) 112.

DP array 102 is implemented as a plurality of interconnected and programmable tiles. The term “tile,” as used herein, means a block or portion of circuitry also referred to as a “circuit block.” As illustrated, DP array 102 includes a plurality of compute tiles 116 organized in an array and optionally a plurality of memory tiles 118. DP array 102 also includes a DP array interface 120 having a plurality of interface tiles 122.

In the example, compute tiles 116, memory tiles 118, and interface tiles 122 are arranged in an array (e.g., a grid) and are hardened or hardwired. Each compute tile 116 can include one or more processors (e.g., cores) and a memory (e.g., a RAM) capable of storing application data used by the core. Each memory tile 118 may include a memory (e.g., a RAM). In one example implementation, cores of compute tiles 116 may be implemented as custom circuits that do not execute program code. In another example implementation, cores of compute tiles 116 are capable of executing program code stored in core-specific program memories contained within each respective processor.

Programmable logic 104 is circuitry that may be programmed to perform specified functions. As an example, programmable logic 104 may be implemented as field programmable gate array type of circuitry. Programmable logic 104 can include an array of programmable circuit blocks. The programmable circuit blocks may include, but are not limited to, RAMs 124 (e.g., block RAMs of varying size), digital signal processing (DSP) blocks 126 capable of performing various multiplication operations, and/or configurable logic blocks (CLBs) 128 each including one or more flip-flops and a lookup table. As defined herein, the term “programmable logic” means circuitry used to build reconfigurable and/or user-specified digital circuits. The topology of programmable logic 104 is highly configurable unlike hardened or hardwired circuitry. Connectivity among the circuit blocks of programmable logic 104 may be specified on a per-bit basis while the tiles of DP array 102 are connected by multi-bit data paths (e.g., streams) capable of packet-based communication. Unlike other hardware systems of SoC 100, programmable logic 104 is distinct in that configuration of programmable logic 104 requires a placed and routed circuit design. That is, a netlist specifying a circuit design undergoes an implementation flow including operations such as synthesis, placement, routing, and bitstream generation.

PS 106 is implemented as hardwired circuitry that is fabricated as part of SoC 100. PS 106 may be implemented as, or include, any of a variety of different processor types each capable of executing program code (e.g., user or application program code). For example, PS 106 may include a central processing unit (CPU) 230, one or more application processing units (APUs) 132, one or more real-time processing units (RPUs) 134, a level 2 (L2) cache 136, an on-chip memory (OCM) 138, and an Input/Output Unit (IOU) 140, each interconnected by a coherent interconnect 142. The example CPU and/or processing units of PS 106 may be implemented using any of a variety of different types of architectures. Example architectures that may be used to implement processing units of PS 106 may include, but are not limited to, an ARM processor architecture, an x86 processor architecture, a graphics processing unit (GPU) architecture, a mobile processor architecture, a DSP architecture, combinations of the foregoing architectures, or other suitable architecture that is capable of executing computer-readable program instructions.

NoC 108 is a programmable interconnecting network for sharing data between endpoint circuits in SoC 100. NoC 108 may be implemented as a packet-switched network. The endpoint circuits can be disposed in DP array 102, programmable logic 104, PS 106, and/or selected HCBs 112. NoC 108 can include high-speed data paths with dedicated switching. In an example, NoC 108 includes one or more horizontal paths, one or more vertical paths, or both horizontal and vertical path(s). NoC 108 is an example of the common infrastructure that is available within SoC 100 to connect selected components and/or subsystems.

Being programmable, nets that are to be routed through NoC 108 may be unknown until a design is created and routed for implementation within SoC 100. NoC 108 may be programmed by loading configuration data into internal configuration registers that define how elements within NoC 108 such as switches and interfaces are configured and operate to pass data from switch to switch and among the NoC interfaces to connect the endpoint circuits. NoC 108 is fabricated as part of SoC 100 (e.g., is hardwired) and, while not physically modifiable, may be programmed to establish logical connectivity between different primary circuits and different secondary circuits of a user circuit design.

Platform manager 110 may be implemented as one or more processors capable of executing program code. Platform manager 110 is capable of managing the other systems across the entirety of SoC 100. Platform manager 110 is capable of maintaining a safe and secure environment, booting SoC 100, and managing SoC 100 during normal operations (e.g., at runtime). For example, platform manager 110 is capable of providing unified and programmable control over power-up, boot/configuration, security, power management, safety monitoring, debugging, and/or error handling for the different hardware systems of SoC 100 (e.g., DP array 102, programmable logic 104, PS 106, NoC 108, and/or HCBs 112).

In one or more embodiments, platform manager 110 operates as a dedicated processor that decouples PS 106 from programmable logic 104. As such, PS 106 and programmable logic 104 may be managed, configured, and/or powered on and/or off independently of one another.

In one or more embodiments, platform manager 110 is capable of executing computer-readable program instructions embodied as firmware. In executing the firmware, platform manager 110 is capable of loading and processing a configuration for SoC 100 embodied as configuration data thereby physically realizing a user design, as specified by the configuration data, in SoC 100. The firmware may be referred to as a “platform loader and manager” or “PLM.” For purposes of illustration, an example implementation of a PLM that is executable by platform manager 110 may be a first stage boot loader or “FSBL.” The firmware, in loading the configuration data for SoC 100, may instantiate different subsystems in SoC 100 as combinations of circuit elements from the various hardware systems described, specify and/or create software domains within SoC 100, and/or program SoC 100 with firewall circuitry configuration data that separates the various subsystems as instantiated.

Each HCB 112 may be implemented as a hardened or hardwired circuit block that may be implemented as a special-purpose or application specific circuit block fabricated as part of SoC 100. In one or more embodiments, each HCB may be considered another example of a system. Though hardwired, HCBs 112 may be configured by loading configuration data into control registers to implement one or more different modes of operation. Examples of HCBs 112 may include input/output (I/O) blocks (e.g., single-ended and pseudo differential I/Os), transceivers for sending and receiving signals to circuits and/or systems external to SoC 100 (e.g., high-speed differentially clocked transceivers), memory controllers, cryptographic engines, digital-to-analog converters (DACs), analog-to-digital converters (ADCs), Universal Asynchronous Receiver-Transmitters (UARTs), Universal Serial Bus (USB) interfaces, and the like. In another aspect, one or more HCBs 112 may implement a RAM or a High Bandwidth memory (HBM).

Various aspects of SoC 100 may be configured, e.g., programmed, initially as part of a boot process. During runtime, aspects of the various hardware systems may be reconfigured. In one aspect, platform manager 110 is capable of initially configuring DP array 102, programmable logic 104, PS 106, and NoC 108 to implement a user design. At any point during runtime, platform manager 110 may reconfigure all or a portion of SoC 100. In some cases, PS 106 may configure and/or reconfigure programmable logic 104 and/or NoC 108 once initially configured by platform manager 110.

SoC 100 is provided as an example. Other example architectures for an SoC may omit certain hardware system(s) described herein and/or include additional hardware system(s) not described herein. Further, the particular hardware systems described herein may be implemented differently to have fewer or more components than shown.

The various hardware systems (e.g., DP array 102, optionally programmable logic 104, PS 106, NoC 108, platform manager 110, and/or HCBs 112) include a variety of control registers illustrated as control registers (CR) 150 in FIG. 1. Though control registers 150 are illustrated in a group, in one or more other embodiments, control registers 150 may be distributed throughout SoC 100. For example, control registers 150 may be distributed in and/or among the various hardware systems controlled by such control registers. Accordingly, control registers 150 control particular functions of the systems such as DP array 102, programmable logic 104, PS 106, NoC 108, platform manager 110, and/or each of HCBs 112. By writing suitable data to a control register 150, the corresponding system may be enabled or disabled, a particular mode of operation may be selected for the system from a plurality of possible operating modes, different firmware configuration options may be selected, interrupts may be specified or set, or the like.

Programmable logic 104 is distinct from hardware systems such as DP array 102, PS 106, NoC 108, platform manager 110, and/or HCBs 112 in that configuration of programmable logic 104 requires a placed and routed circuit design. That is, a netlist specifying the circuit design to be implemented in programmable logic 104 undergoes an implementation flow including operations such as synthesis, placement, routing, and bitstream generation. The placed and routed circuit design may be embodied as configuration data such as a bitstream. The circuitry specified by the netlist may be physically realized in programmable logic 104 by loading the data/bitstream into configuration memory cells (not shown) of programmable logic 104. Changing an aspect of circuitry implemented in programmable logic 104 requires that the implementation flow be performed anew on the modified netlist or on the netlist using modified compilation options.

In view of the foregoing, it may be seen that particular aspects of SoC 100 or other SoCs similar thereto may be configured (e.g., programmed) by writing to particular control registers 150 without disturbing or otherwise affecting the configuration data for the SoC that specifies an implementation of a netlist within programmable logic 104.

Throughout this disclosure, SoC 100 is referenced. It should be appreciated that the inventive arrangements may be used with any of a variety of SoCs that include programmable logic and one or more other hardware systems such that one or more configuration settings for the SoC may be changed without affecting or otherwise disturbing the configuration data that specifies a netlist and/or circuit implementation within the programmable logic.

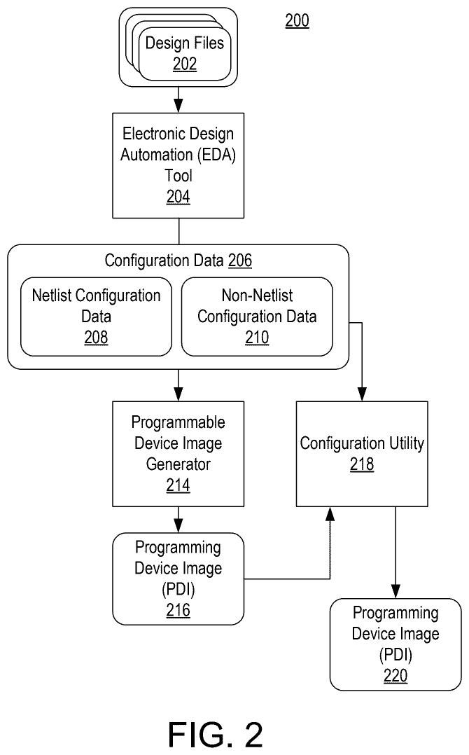

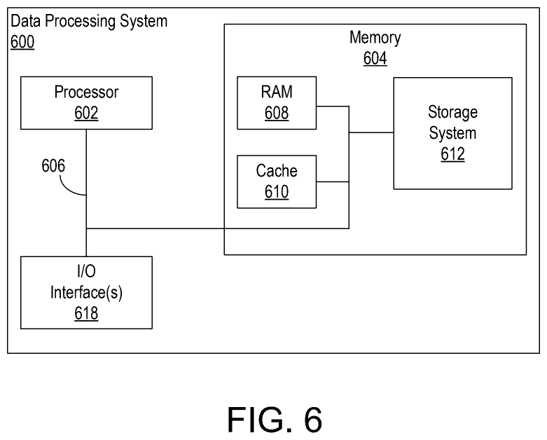

FIG. 2 illustrates an architecture 200 in accordance with one or more embodiments of the disclosed technology. Architecture 200 is an executable architecture that may be specified as or using computer-readable program instructions that are executable by a data processing system. An example of a data processing system that is capable of executing architecture 200 of FIG. 2 is described in connection with FIG. 6.

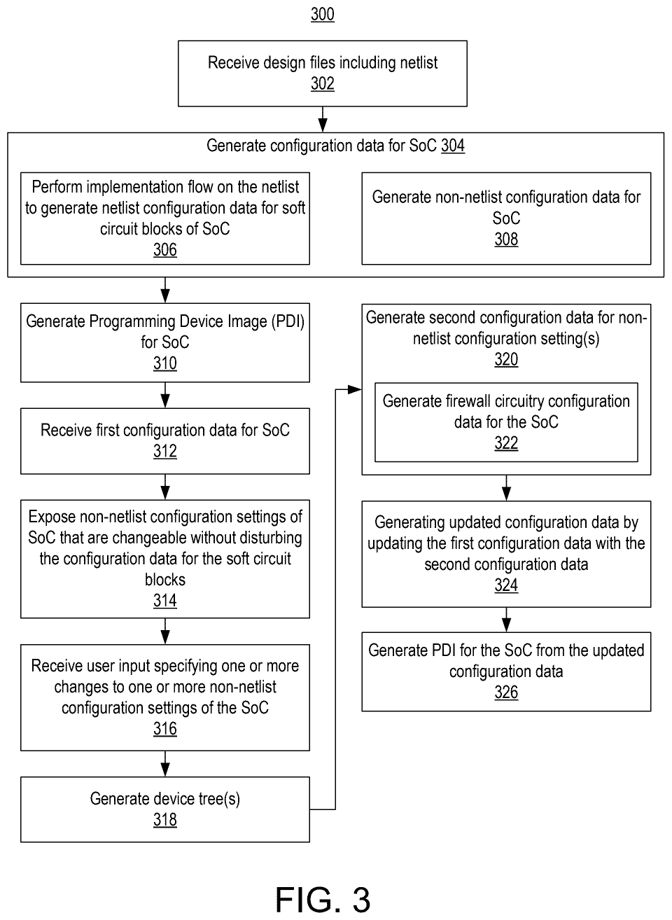

FIG. 3 illustrates a method 300 of operation for software architecture 200 in accordance with one or more embodiments of the disclosed technology. Referring to FIGS. 2 and 3 collectively, in block 302, the EDA tool 204 receives design files 202 specifying a design for an SoC such as SoC 100. The design may be a user-specified design. Design files 202 include a netlist that is to be implemented in programmable logic 104 of SoC 100 or a region of programmable logic 104. Design files 202 also include other settings for different hardware systems of SoC 100.

In one or more embodiments, design files 202 may specify or define one or more subsystems to be created within SoC 100. In general, each subsystem will include one or more circuit blocks of the various hardware systems. The circuit blocks may be hard circuit blocks, soft circuit blocks in reference to circuitry implemented in programmable logic 104, or a combination of both hard and soft circuit blocks. In most cases, each subsystem will include a primary (e.g., a manager) circuit block and one or more secondary (e.g., worker) circuit blocks, though this need not be the case in every instance. The primary circuit block is the controlling circuit block. The secondary circuit block(s) are controlled by and/or respond to the primary circuit block. Design files 202 may specify a particular number of subsystems, which circuit blocks of the SoC are members in each subsystem, which circuit blocks are designated as primary and which are designated as secondary, and optionally a software domain for the subsystem(s).

As an illustrative and non-limiting example, a first subsystem may include CPU 130 as the primary circuit block and one or more other circuit blocks as peripheral devices or secondary circuit blocks of CPU 130. A second subsystem may include APU 132 as the primary circuit block and one or more other circuit blocks as peripheral devices or secondary circuit blocks of APU 132. Yet another subsystem may include RPU 134 as the primary circuit block and one or more circuit blocks as peripheral devices or secondary circuit blocks to RPU 134. In some cases, circuit blocks operating as peripheral devices may be shared among different subsystems. In other cases, circuit blocks operating as peripheral devices may not be shared, meaning that a given subsystem has exclusive access or control over such peripheral device(s). Design files 202 may specify such information for each subsystem.

Design files 202 also may specify a software domain for each subsystem. The software domain defines the particular software that will execute in each respective subsystem in the case where the subsystem includes a hardware processor. Examples of different software domains may include a LINUX operating system, a WINDOWS operating system, a Real-Time Operating System (RTOS), a hypervisor, or whether the subsystem executes program code without an operating system (e.g., as bare metal). The domain also may specify a particular variety (e.g., provider) and/or build of each operating system, hypervisor, or application.

In block 304, EDA tool 204 generates configuration data 206 for SoC 100. In the example of FIG. 3, block 304 includes blocks 306 and 308. Blocks 306 and 308 may be performed in parallel, serially, and/or iteratively. In general, in block 306, EDA tool 204 is capable of performing an implementation flow on the particular design files that specify the netlist to be physically realized in programmable logic 104. For example, EDA tool 204 is capable of performing synthesis, placement, and routing on the design files that specify the netlist. With the netlist being placed and routed, EDA tool 204 is capable of generating netlist configuration data 208. Netlist configuration data 208 specifies an implementation of the netlist within programmable logic 104 as one or more soft circuit blocks (e.g., circuit blocks formed of programmable logic 104). In one or more embodiments, EDA tool 204 is capable of outputting the configuration data as one or more Configuration Data Objects (CDOs).

In one or more embodiments, a CDO is implemented as a binary file. In one or more other embodiments, the CDO may be implemented as a text file. Each CDO may include values and/or information that may be written to particular locations, e.g., control registers or configuration memory cells as the case may be, in SoC 100 to configure SoC 100 as part of a boot process and/or as part of a reconfiguration (e.g., whether full or partial) operation for SoC 100. In an example implementation, a CDO may be specified as a set of configuration commands. Each configuration command may be implemented as binary data specifying a single command within a CDO. Examples of configuration commands may include, but are not limited to, a register write or a mask write.

In the case of programmable logic 104, the CDO(s) are generated specifying the placed and routed circuit design, e.g., a bitstream. The data from the CDO(s) specifying the bitstream may be loaded into configuration memory cells (not shown) of programmable logic 104. Loading the configuration data for soft circuit blocks, whether as one or more CDOs or in another format, physically realizes the netlist from design files 202, as placed and routed, within programmable logic 104.

In block 308, EDA tool 204 generates non-netlist configuration data 210 for SoC 100. Non-netlist configuration data 210 is configuration data for portions of SoC 100 other than programmable logic 104 and that may be changed without affecting the implementation of the netlist in programmable logic 104. Non-netlist configuration data 210 may include configuration data for DP array 102, PS 106, NoC 108, platform manager 110, one or more HCBs 112, and/or firmware for SoC 100. In general, non-netlist configuration data 210 also may be output as one or more CDOs.

In one or more embodiments, each CDO may include the configuration data for a particular one of the hardware systems of SoC 100. In one or more other embodiments, a CDO may include configuration data for more than one hardware system of SoC 100. In one or more other embodiments, more than one CDO may include configuration data for a single hardware system of SoC 100.

In the example of FIG. 2, netlist configuration data 208 and non-netlist configuration data 210 are differentiated for purposes of illustration. In general, EDA tool 204 is capable of outputting configuration data 206 that includes a plurality of CDOs, where one or more CDOs are used to configure programmable logic 104 and one or more other CDOs are used to configure the other hardware systems of SoC 100. In some cases, a given CDO may include configuration data for programmable logic 104 (e.g., netlist configuration data) and one or more other systems of SoC 100 (e.g., non-netlist configuration data).

In one or more embodiments, CDOs may be generated or organized according to power domains implemented in SoC 100. For example, those circuit elements of the various hardware systems assigned to a same power domain in that such circuit elements are powered on or off together as a group, may have a same or common CDO providing the configuration data for the respective circuit elements.

In the example of FIG. 3, blocks 306 and 308 are shown within block 304 as the operations represented by blocks 306 and 308 may have one or more dependencies that require the operations to interact with one another and/or share data to generate correct configuration data for SoC 100. Whether blocks 306 and 308 are performed in parallel, serially, and/or iteratively, the operations represented by blocks 304 and 306 may exchange data in generating the respective types of configuration data for SoC 100.

In block 310, optionally, a programming device image (PDI) generator 214 is capable of generating a PDI 216. In one or more embodiments, PDI generator 214 generates PDI 216 by concatenating the CDOs of configuration data 206. For example, PDI 216 may include configuration data for DPE array 102, configuration data for programmable logic 104, configuration data for PS 106, configuration data for NoC 108, and/or configuration data for HCBs 112. PDI generator 214 is also capable of including header information in PDI 216 indicating the location or start and stop (or length) of each CDO included in PDI 216.

Blocks 302-310 illustrate general operations performed to implement a design for an SoC such as SoC 100. Beginning in block 312, another process or phase of the process may begin that operates on configuration data 206 as generated by EDA tool 204. More particularly, beginning in block 312, configuration utility 218 may be used to update certain portions of configuration data 206 and, in particular, one or more portions of non-netlist configuration data 210. In one or more embodiments, configuration utility 218 is capable of operating on non-netlist configuration data 210 (e.g., one or more CDOs). Non-netlist configuration data 210, for example, may be stored in a particular directory that is accessible by configuration utility 218. In one or more other embodiments, configuration utility 218 is capable of operating on PDI 216. In the case of operating on PDI 216, for example, configuration utility 218 may extract the relevant CDO(s) from PDI 216, e.g., those CDOs that include the non-netlist configuration data 210.

In either case, configuration utility 218 is capable of generating updated configuration data. In one or more embodiments, configuration utility 218 is capable of generating updated configuration data by, at least in part, generating new versions of one or more CDOs. In one or more other embodiments, configuration utility 218 is capable of generating the updated configuration data by performing a merge operation that overwrites existing portions of one or more CDOs with the modified configuration data.

Accordingly, in block 312, configuration utility 218 is capable of receiving first configuration data for SoC 100. For example, configuration utility 218 may receive configuration data 206 from a data storage device. In another example, configuration utility 218 extracts configuration data 210 from PDI 216.

In block 314, configuration utility 218 is capable of exposing non-netlist configuration settings of SoC 100. Non-netlist settings of SoC 100, as noted, are configuration settings of SoC 100 that, if changed, have no impact or effect on an implementation of a netlist implemented in programmable logic 104 of SoC 100. Non-netlist settings may include, but are not limited to, configuration settings for hard (e.g., hardwired or hardened) circuit blocks of SoC 100, configuration settings for firmware of SoC 100, and/or configuration settings for one or more subsystems of SoC 100.

Appreciably, the particular non-netlist configuration settings available to the user for modification via configuration utility 218 will vary based on the particular target SoC (e.g., make and/or model) that will be used to implement the user's design. In exposing the non-netlist configuration settings, configuration utility 218 may generate a user interface that displays current values for one or more non-netlist configuration settings of SoC 100 and through which a user may specify a change to such values.

In one or more embodiments, configuration utility 218 may include a library of configuration settings for one or more different target SoCs where the individual configuration settings are annotated or otherwise associated with a particular target SoC and as being netlist configuration settings or non-netlist configuration settings. In one or more embodiments, the library may also indicate which CDO the respective configuration settings are included and/or the particular location of such configuration setting(s) within the respective CDOs. Accordingly, configuration utility 218 is capable of exposing the non-netlist configuration settings to a user by generating and/or displaying a user interface that presents the non-netlist configuration settings of the SoC. A user may access the user interface to change or modify the non-netlist configuration settings.

Referring to configuration settings for hard circuit blocks, examples of such configuration settings may include, but are not limited to, a configuration setting that specifies a change in a state of enablement of a hard circuit block. Such a configuration setting may specify a change that enables or activates a hard circuit block that was not enabled or activated in the first configuration data. Alternatively, such a configuration setting may specify a change that disables or deactivates a hard circuit block that was enabled or activated in the first configuration data.

One or more of the non-netlist configuration settings for hard circuit blocks may specify whether a given processor is secure. An operating system such as LINUX as may be executed by a processor may be configured with a listing of services and/or functions available from platform manager 110 in executing the PLM. The functions of platform manager 110 may be requested by other processors via inter-processor interrupt (IPI) channel(s) of SoC 100. Whether a given processor is able to access a given function or service of platform manager 110 may depend on whether the requesting processor is designated secure or not by the non-netlist configuration settings for the hard circuit block.

Referring to configuration settings for firmware, examples of such configuration settings may include, but are not limited to, a configuration setting that specifies a change or modification in or to error handling within SoC 100. Another example is a configuration parameter that specifies a change or modification in or to an IPI channel for SoC 100. For example, one or more of control registers 150 may specify which processor(s) are assigned to each IPI channel of SoC 100 and are therefore able to communicate by way of the IPI channel.

Another example of a configuration setting for firmware of SoC 100 is one that points to a particular region of memory and/or program code that informs or instructs the firmware how to perform a particular task. A change to the firmware may be specified as a configuration setting that specifies an address of program code, for example, to be executed under certain conditions. Changing the address of the configuration setting may therefore change the particular operations to be performed under a given set of conditions detected in and/or by SoC 100.

For purposes of illustration, the non-netlist configuration setting may specify a particular type of error handling for an HCB 112, for CPU 130, for APU 132, and/or for RPU 134. In another example, a given processor, whether CPU 130, APU 132, RPU 134, or platform manager 110, may be tasked with error handling for a memory controller detecting a particular type of error such as an uncorrectable bit error. An example of a change in a non-netlist configuration setting may be to choose a new or different response to the error for the responsible processor such as reset SoC 100, re-initiate the data transfer, or report the error to another circuit block, processor, and/or subsystem of SoC 100.

Referring to configuration settings for subsystems, examples of such configuration parameters may include, but are not limited to, a configuration parameter that specifies a change in subsystem membership of a hard circuit block. Such a change may add a hard circuit block to an existing subsystem, remove a hard circuit block from an existing subsystem, move a hard circuit block from one subsystem to a different subsystem of the SoC, create an entirely new subsystem having one or more hard circuit blocks as members, or delete an entire subsystem.

As noted, the user's design may specify one or more subsystems. An example of a subsystem may include a processor capable of executing program code and one or more peripheral devices such as a UART implemented as a hard circuit block (e.g., an HCB 112 of SoC 100). SoC 100 may include multiple UARTs. The user design may specify which UART(s), if any, are members of a subsystem. An example of a configuration parameter for a subsystem that specifies a change may add a UART to the subsystem, remove a UART from the subsystem, or move a UART from the subsystem (e.g., a first subsystem) to a different subsystem (e.g., a second subsystem).

For purposes of illustration, consider an example in which a first subsystem is formed of APU 132 and one or more peripherals that are HCBs 112. As noted, one or more of the HCBs 112 may be a UART. Other examples may be transceivers. One or more of HCBs 112 may be reassigned from the subsystem including APU 132 to a second and different subsystem that includes RPU 134 by changing the value of one or more non-netlist configuration settings.

Subsystem membership, in reference to non-netlist configuration settings that define which circuit elements of SoC 100 are members of different subsystems, may be used to specify security settings for firewall circuitry that permit circuit elements that are in the same subsystem to communicate while preventing circuit elements disposed in different subsystems from communicating.

Appreciably, in some cases, a modification of a first non-netlist configuration setting may have a dependency with a second and different non-netlist configuration setting thereby requiring that the second non-netlist configuration setting also be modified in response to modification of the first non-netlist configuration setting. For example, in order to include a hard circuit block in a particular subsystem, that hard circuit block must be enabled. Thus, in order to include a hard circuit block within a specified subsystem, configuration utility 218 may update non-netlist configuration settings to enable the hard circuit block and, in response to modifying the first non-netlist configuration setting, update one or more further non-netlist configuration settings for the subsystem specifying that the hard circuit block is a member of that subsystem. The library of non-netlist configuration settings may specify dependencies among the various configuration settings therein. In one or more embodiments, a hard circuit block that is disabled or deactivated may have no power (e.g., be off), be clock gated, or otherwise be placed in a lower power mode.

In one or more embodiments, a change to a non-netlist configuration setting for a subsystem may include one that changes a software domain of the subsystem. As an illustrative and non-limiting example, a change in a software domain may include a change in the operating system executed by a processor (e.g., a hard circuit block) of a subsystem from a first operating system to a second and different operating system, changing the subsystem so that the processor executes a hypervisor in lieu of a particular operating system, changing the subsystem so that the processor executes a particular operating system instead of a hypervisor, changing the subsystem such that the processor executes an application (e.g., a bare metal application), or changing the subsystem such that the processor executes a different application therein (whether bare metal or on top of a particular operating system).

In block 316, configuration utility 218 is capable of receiving user input specifying one or more changes to one or more non-netlist configuration settings of SoC 100. The one or more changes, for example, may specify a different value to be written to a particular address of control register 150 pertaining to a particular hard circuit block of SoC 100.

In block 318, a device tree generator is capable of generating a device tree for one or more of the different subsystems of SoC 100. For example, configuration utility 218 is capable of providing the non-netlist configuration data 210 as well as user input received in block 316 to a device tree generator (e.g., a computer program) that is capable of generating a device tree for one or more subsystems of the user's design. As an illustrative and non-limiting example, a subsystem may have a software domain that executes LINUX or another operating system. In that case, the device tree generator detects membership of hard circuit blocks within the subsystem and generates a device tree that instantiates any drivers that are required for the processor of the subsystem to communicate with the various instance(s) of the hard circuit blocks included in the subsystem. In this example, the device tree(s) as generated may replace existing device tree(s).

In block 320, configuration utility 218 is capable of generating second configuration data for the changed non-netlist configuration settings. That is, configuration utility 218 is capable of generating second configuration data for the non-netlist configuration settings specified by the user input received in block 314. In one or more embodiments, the second configuration data specifies only the change or changes that have been specified, which encompass only changes to non-netlist configuration settings. In one or more embodiments, configuration utility 218 is capable of generating second configuration data by generating the binary data for the new and/or updated non-netlist configuration settings. The binary data may be, or include, a plurality of configuration commands to be merged into one or more CDOs.

Configuration utility 218 may perform block 322 as part of block 320. In block 322, configuration utility 218 is capable of generating firewall circuitry configuration data for SoC 100 based on the configuration data. The firewall circuitry configuration data is data used to program firewall circuitry included in SoC 100. The firewall circuity implements isolation between the subsystems as defined by the configuration data. In this example, configuration utility 218 is capable of generating the firewall circuitry configuration data directly from the configuration data as updated and, as such, directly from the user inputs as no further user interaction is required. As such, the firewall circuitry that prevents unauthorized transactions and/or data movement between different subsystems and/or circuit blocks of SoC 100 may be derived directly from the configuration data such that separate user input explicitly specifying a firewall configuration for SoC 100 is not required.

In one or more embodiments, firewall circuitry, e.g., firewall circuit blocks, may be included in the example of FIG. 1. In one or more embodiments, the firewall circuit blocks may be disposed at entry and/or exit points of NoC 108, on interfaces to primary circuit blocks, and/or on interfaces to peripheral or secondary circuit blocks. Firewall circuit blocks, for example, may pass transactions that are permissible and reject, delete, or drop transactions that are not permissible. If a primary is not permitted to access a particular peripheral or a particular address range of the peripheral, the firewall circuit, whether on the interface of the primary circuit block, on the interface to the peripheral, and/or along the path within SoC 100 between the two entities, will reject the transaction. The firewall circuits may be programmed, for example, with configuration data specifying identifiers of primary circuits and/or secondary circuit that are permitted to pass transactions through the firewall circuit(s). The firewall circuits also may be programmed with allowable address ranges to be accessed by particular primary circuits and/or secondary circuits.

In block 324, configuration utility 218 is capable of generating updated configuration data by updating the first configuration data with the second configuration data. Configuration utility 218, for example, is capable of merging the second configuration data as generated into the first configuration data. The merging leaves the portion of the first configuration data specifying the circuit design unchanged. In performing the merger, the second configuration data overwrites any existing and corresponding portions of the first configuration data. This may include overwriting previously empty portions of the first configuration data or portions of the first configuration data specifying default values with the newly generated second configuration data.

In updating the first configuration data with the second configuration data, the portion of the first configuration data specifying the circuit design (e.g., the netlist as placed and routed for implementation in programmable logic 104) is left unchanged. In other words, the circuit design for the programmable logic is unaffected by the change(s) to the non-netlist configuration settings of SoC 100 described herein. Appreciably, one or more or all of the non-netlist configuration settings of the first configuration data will be modified or replaced by the second configuration data.

In one or more embodiments, for each CDO that has changed, configuration utility 218 is capable of generating a new version of that CDO that incorporates the changes embodied as the second configuration data. It should be appreciated new versions of CDOs may be generated using any of a variety of techniques. For example, rather than overwriting CDOs, configuration utility 218 may store the newly generated CDOs in a new file and/or directory and copy the CDOs that have not changed into the new directly resulting in the updated configuration data.

In one or more other embodiments, configuration utility 218 is capable of generating the second configuration data as new binary data corresponding to each user-specified change. In that case, configuration utility 218 is capable of selecting the particular CDO(s) that include the non-netlist configuration setting(s) that have changed, and updating the respective CDOs (e.g., updating only the relevant or changed portions of such CDOs rather than generating new versions of CDOs). As noted in the prior example, configuration utility 218 may create a copy of the CDOs prior to applying any changes as described.

In one or more embodiments, configuration utility 218 may store a mapping of non-netlist configuration settings to particular CDOs and/or portions of CDOs. For example, the mapping may be maintained in the previously described library, whether specified as a database or other data structure. In some cases, the non-netlist configuration settings of CDOs may be indicated using a series of markers allowing entire sections of CDOs to be updated or replaced by way of the merger operation. For example, the merger may replace a portion of first configuration data embodied as a section of a CDO with a portion of second configuration data based on the mapping. By performing the merger operation that overwrites or replaces portions of first configuration data with corresponding portions of second configuration data in lieu of generating new CDOs, a significant reduction in runtime may be achieved. That is, the generation of new CDOs may be time consuming such that the merging process described where the second configuration data overwrites corresponding portions of the first configuration data in existing CDOs can significantly reduce runtime of configuration utility 218.

In block 326, configuration utility 218 is capable of generating a PDI 220 for SoC 100 from the updated configuration data. For example, configuration utility 218 is capable of combining the CDOs that are newly generated or updated with CDOs that have not changed to create a newly generated PDI 220. PDI 220 includes the user specified changes to the non-netlist configuration settings of SoC 100 and preserves the existing configuration data for soft circuit blocks (e.g., circuitry implemented in programmable logic 104) from the first configuration data unchanged.

In one or more embodiments, as part of block 326, configuration utility 218 is capable of also including software artifacts such as any generated device trees and/or firewall circuitry configuration data within PDI 220. In one or more example implementations, the software artifacts and the firewall circuitry configuration data may be embodied as one or more CDOs that may be included in PDI 220.

Having generated PDI 220, PDI 220 may be loaded into SoC 100 to implement the user design therein. For example, PDI 220 may be loaded into SoC 100 from a data storage device, as downloaded from a computer system, or the like. Firmware within SoC 100 executed by platform manager 110 may load PDI 220, which configures control registers 150 and/or configuration memory cells of programmable logic 104 thereby physically realizing the user design within SoC 100.

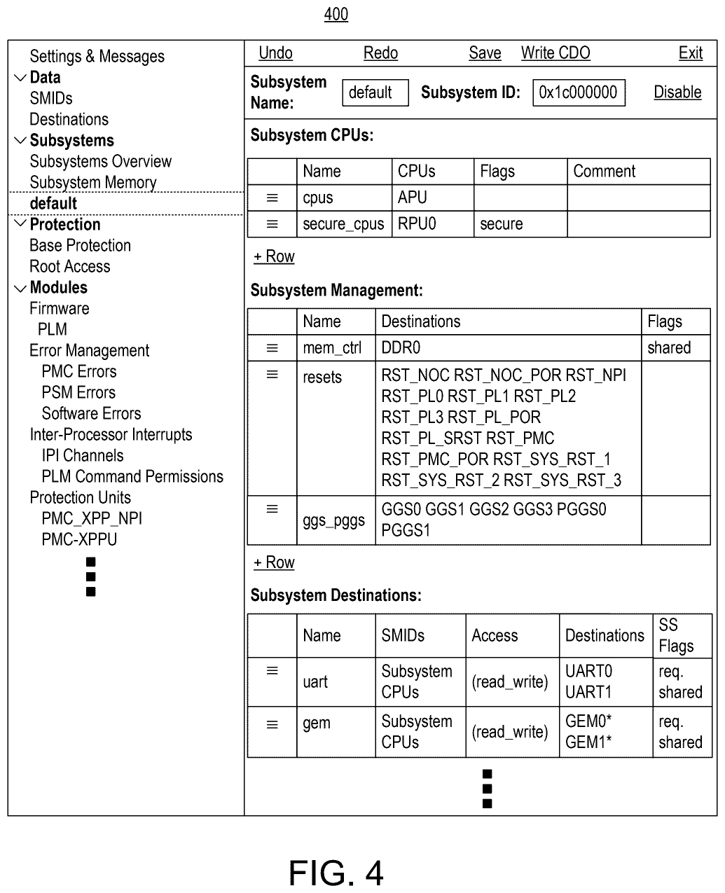

FIG. 4 illustrates a user interface 400 of configuration utility 218 in accordance with one or more embodiments of the disclosed technology. User interface 400 illustrates an example in which the user may create and/or define particular subsystems of a user design. In the example of FIG. 4, a subsystem named “default” has been created by the first configuration data. In the example, configuration utility 218 exposes different non-netlist configuration settings that allow the user to define which hard circuit blocks are included in the subsystem and various other configuration settings for the hard circuit blocks.

For example, in the “Subsystem CPUs” section of user interface 400, the user may change (e.g., add or remove) CPUs included in the default subsystem and specify whether the CPUs are secure. In the “Subsystem Management” section of user interface 400, the user may change the particular memory controller (mem_ctrl) included in the default subsystem, specify the particular memory (DDR0) accessible by the CPU(s) in the default subsystem, and specify whether that memory is shared with other subsystem(s) of SoC 100. In the “Subsystems Destinations” section of user interface 400, the user may change additional hard circuit blocks included in the subsystem as peripheral or secondary devices. In the example, the default subsystem includes additional hard circuit blocks such as a UART and a Gigabit Ethernet Controller (GEM). The user may specify the type of access (e.g., read, write, read and write), the particular instance of each hard circuit block in cases where SoC 100 includes more than one instance of the various hard circuit blocks listed. In this example, the default subsystem includes UARTS 0 and 1 and GEMs 0 and 1. Further, the user may specify whether the hard circuit blocks are shared.

In the example of FIG. 4, data indicating whether a hard circuit block is shared may be directly translated into the firewall circuitry configuration data used to program the firewall circuitry. That is, in cases where the hard circuit block is shared, the firewall circuit block(s) that regulate access to the hard circuit block is programmed to pass transactions (e.g., requests) from circuit blocks and/or systems external or not included in the default subsystem. In cases where the hard circuit block is not shared, the firewall circuit block(s) that regulate access to the hard circuit block is programmed to pass only transactions that originate from other circuit blocks that are members of the default subsystem (e.g., in the same subsystem). Similarly, in the case where a region of memory is shared, the firewall circuit block(s) that regulate access to the memory is programmed to allow hard circuit blocks of other subsystems to access the region of memory (e.g., to allow access to a particular address range). In the case where the region of memory is not shared, the firewall circuit block(s) that regulate access to the memory is programmed to allow only hard circuit blocks that are members of the subsystem to access the region of memory.

In the example of FIG. 4, the user may create further subsystems, delete subsystems, and specify any of the various non-netlist configuration settings for any subsystems created and/or listed in user interface 400.

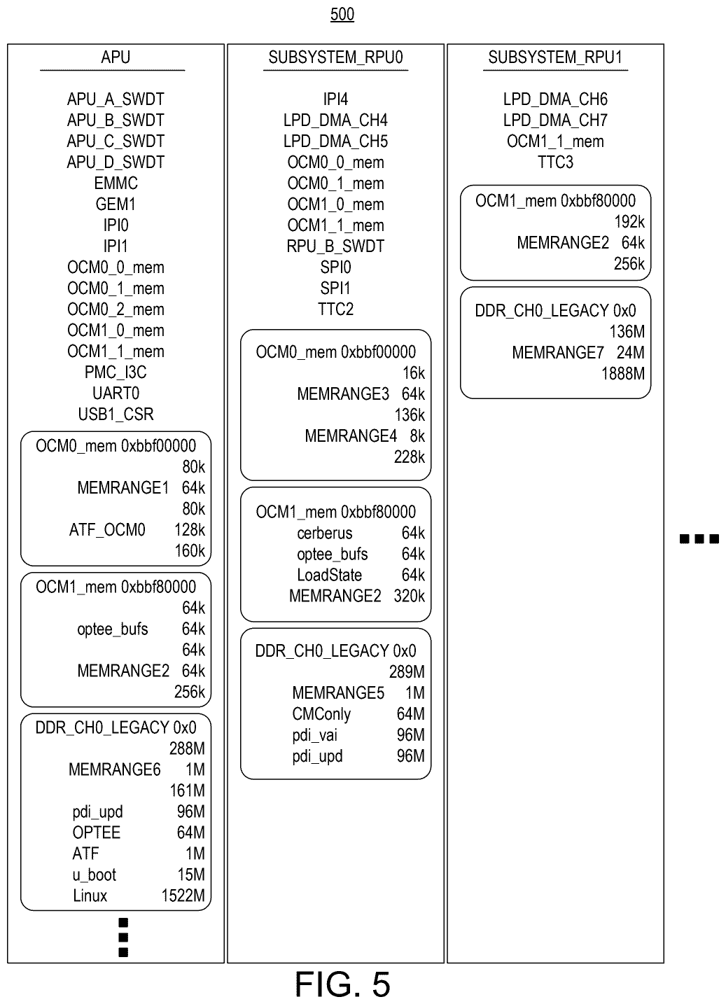

FIG. 5 illustrates a user interface 500 of configuration utility 218 in accordance with one or more embodiments of the disclosed technology. In the example of FIG. 5, user interface 500 illustrates three different subsystems where each subsystem is illustrated as a column of hard circuit blocks of SoC 100. As illustrated, the subsystems include APU, subsystem_RPU0, and subsystem_RPU1.

The APU subsystem includes APU 132, on chip memories OCM0 and OCM1 with the defined memory address ranges, and DDR memory with the defined address ranges and/or data stored at the respective addresses indicated. As shown, the APU subsystems uses IPI channels 0 and 1, includes GEM1, UART0, a USB, and other hard circuit blocks of SoC 100. Each of the parameters illustrated in the APU subsystem may be edited as a non-netlist configuration setting.

Subsystem_RPU0 includes an IPI channel, two DMA channels, and other peripherals such as two Serial-Peripheral Interfaces (SPIs), and triple-timer/counter (TTC). Each of the parameters illustrated in the subsystem_RPU0 may be edited as a non-netlist configuration setting. Subsystem_RPU1 includes two DMA channels and one TTC. Each of the parameters illustrated in subsystem_RPU1 may be edited as a non-netlist configuration setting.

With respect to generating firewall configuration data, as may be observed, the portion of memory of SoC 100 denoted as MEMRANGE3 is only included in subsystem_RPU0. This means that firewall configuration data is generated that programs or configures the relevant firewall circuit(s) to only allow the CPU and DMA channels for subsystem_RPU0 subsystem to access this memory and/or particular portion or range of memory. The firewall circuit(s) will block or prevent other CPUs and other primary circuits outside of subsystem_RPU0 from accessing MEMRANGE3.

In one or more embodiments, the examples of FIGS. 4 and 5 may be existing subsystems already defined in the first configuration data that the user may modify as described herein using configuration utility 218. In one or more other embodiments, the examples of FIGS. 4 and 5 may be illustrative of cases where the user creates or defines a new subsystem using configuration utility 218 that was not defined in the first configuration data. In still another example, the user may delete one or more of the subsystems illustrated in its entirety.

FIG. 6 illustrates an example implementation of a data processing system 600. As defined herein, the term “data processing system” means one or more hardware systems configured to process data, each hardware system including at least one processor and memory, wherein the processor is programmed with computer-readable program instructions that, upon execution, initiate or perform operations. Data processing system 600 can include a processor 602, a memory 604, and a bus 606 that couples various system components including memory 604 to processor 602.

Processor 602 may be implemented as one or more processors. In an example, processor 602 is implemented as a hardware processor such as a central processing unit (CPU). Processor 602 may be implemented as one or more circuits capable of carrying out instructions contained in program code. The circuit(s) may be an IC or embedded in an IC. Processor 602 may be implemented using a complex instruction set computer architecture (CISC), a reduced instruction set computer architecture (RISC), a vector processing architecture, or other known architecture. Example processors include, but are not limited to, processors having an x86 type of architecture (IA-32, IA-64, etc.), Power Architecture, ARM processors, and the like.

Bus 606 represents one or more of any of a variety of communication bus structures. By way of example, and not limitation, bus 606 may be implemented as a Peripheral Component Interconnect Express (PCIe) bus. Data processing system 600 typically includes a variety of computer system readable media. Such media may include computer-readable volatile and non-volatile media and computer-readable removable and non-removable media.

Memory 604 can include computer-readable media in the form of volatile memory, such as random-access memory (RAM) 608 and/or cache memory 610. Data processing system 600 also can include other removable/non-removable, volatile/non-volatile computer storage media. By way of example, storage system 612 can be provided for reading from and writing to a non-removable, non-volatile magnetic and/or solid-state media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 606 by one or more data media interfaces. Memory 604 is an example of at least one computer program product.

Memory 604 is capable of storing computer-readable program instructions that are executable by processor 602. For example, the computer-readable program instructions can include an operating system, one or more application programs, other program code, and program data. Processor 602, in executing the computer-readable program instructions, is capable of performing the various operations described herein that are attributable to a computer. In one or more examples, the computer-readable program instructions may implement the architecture 200 of FIG. 2, e.g., EDA tool 204, configuration utility 218, and/or PDI generator 214.

Data processing system 600 may include one or more Input/Output (I/O) interfaces 618 communicatively linked to bus 606. I/O interface(s) 618 allow data processing system 600 to communicate with one or more external devices and/or communicate over one or more networks such as a local area network (LAN), a wide area network (WAN), and/or a public network (e.g., the Internet). Examples of I/O interfaces 618 may include, but are not limited to, network cards, modems, network adapters, hardware controllers, etc. Examples of external devices also may include devices that allow a user to interact with data processing system 600 (e.g., a display, a keyboard, and/or a pointing device) and/or other devices such as an accelerator card.

Data processing system 600 is only one example implementation. Data processing system 600 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

The example of FIG. 6 is not intended to suggest any limitation as to the scope of use or functionality of example implementations described herein. Data processing system 600 is an example of computer hardware that is capable of performing the various operations described within this disclosure. In this regard, data processing system 600 may include fewer components than shown or additional components not illustrated in FIG. 6 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

The terminology used herein is for the purpose of describing particular embodiments only and is not intended to be limiting. Notwithstanding, several definitions relevant to this disclosure are presented below.

As defined herein, the singular forms “a,” “an,” and “the” are intended to include the plural forms as well, unless the context clearly indicates otherwise.

As defined herein, the terms “at least one,” “one or more,” and “and/or,” are open-ended expressions that are both conjunctive and disjunctive in operation unless explicitly stated otherwise.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of a computer-readable storage medium or two or more computer-readable storage mediums. A non-exhaustive list of examples of a computer-readable storage medium include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a double-data rate synchronous dynamic RAM memory (DDR SDRAM or “DDR”), a portable compact disc read-only memory (CD-ROM), a digital versatile disk (DVD), a memory stick, a floppy disk, or the like.

As defined herein, the phrase “in response to” and the phrase “responsive to” means responding or reacting readily to an action or event. The response or reaction is performed automatically. As defined herein, the term “automatically” means without human intervention. Thus, if a second action is performed “responsive to” a first action, there is a causal relationship between an occurrence of the first action and an occurrence of the second action. The term “responsive to” indicates the causal relationship.

The term “user”refers to a human being.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a controller, and a Graphics Processing Unit (GPU).

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium (or mediums) having computer-readable program instructions thereon for causing a processor to carry out aspects of the inventive arrangements described herein. Within this disclosure, the terms “program code,” “program instructions,” and “computer-readable program instructions” are used interchangeably. Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives program instructions from the network and forwards the computer-readable program instructions for storage in a computer-readable storage medium within the respective computing/processing device.

Program instructions for carrying out operations for the inventive arrangements described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Program instructions may include state-setting data. The program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the program instructions by utilizing state information of the program instructions to personalize the electronic circuitry, in order to perform aspects of the inventive arrangements described herein.

Certain aspects of the inventive arrangements are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by program instructions, e.g., program code.

These program instructions may be provided to a processor of a computer, special-purpose computer, or other programmable data processing apparatus to produce a machine, such that the program instructions, which execute via the processor of the computer or other programmable data processing apparatus, create means for implementing the functions/acts specified in the flowchart and/or block diagram block or blocks. These program instructions may also be stored in a computer-readable storage medium that can direct a computer, a programmable data processing apparatus, and/or other devices to function in a particular manner, such that the computer-readable storage medium having program instructions stored thereon comprises an article of manufacture including program instructions which implement aspects of the operations specified in the flowchart and/or block diagram block or blocks.

The program instructions may also be loaded onto a computer, other programmable data processing apparatus, or other device to cause a series of operations to be performed on the computer, other programmable apparatus or other device to produce a computer implemented process, such that the program instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the inventive arrangements. In this regard, each block in the flowchart or block diagrams may represent a module, segment, or portion of instructions, which comprises one or more program instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and program instructions.

The descriptions of the various embodiments of the disclosed technology have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
receiving, by computer hardware, first configuration data for a System-on-Chip (SoC), wherein the SoC has a plurality of hardware systems including programmable logic and the first configuration data includes a portion specifying a circuit design for the programmable logic;
receiving, by the computer hardware, a user input specifying a change to a non-netlist configuration setting of the SoC;
generating, by the computer hardware, second configuration data for the SoC, wherein the second configuration data specifies the change to the non-netlist configuration setting; and
generating, by the computer hardware, updated configuration data for the SoC by merging the second configuration data with the first configuration data leaving the portion of the first configuration data specifying the circuit design unchanged.

2. The method of claim 1, wherein the non-netlist configuration setting includes a configuration setting for a hard circuit block of the SoC.

3. The method of claim 2, wherein the change modifies a state of enablement of the hard circuit block of the SoC as specified by the first configuration data.

4. The method of claim 2, wherein the change modifies subsystem membership of the hard circuit block.

5. The method of claim 1, wherein the non-netlist configuration setting includes a configuration setting for firmware of the SoC.

6. The method of claim 5, wherein the change specifies a modification to error handling within the SoC.

7. The method of claim 5, wherein the change specifies a modification to an inter-processor interrupt channel of the SoC.

8. The method of claim 1, wherein the circuit design is placed and routed and the circuit design for the programmable logic is unaffected by the change to the non-netlist configuration setting of the SoC.

9. The method of claim 1, wherein the second configuration data specifies only the change.

10. The method of claim 1, further comprising:
automatically generating firewall circuitry configuration data based on the updated configuration data for the SoC.

11. A system, comprising:
a memory capable of storing computer-readable program instructions; and
a hardware processor capable of executing the computer-readable program instructions to perform operations including:
receiving first configuration data for a System-on-Chip (SoC), wherein the SoC has a plurality of hardware systems including programmable logic and the first configuration data includes a portion specifying a circuit design for the programmable logic;
receiving a user input specifying a change to a non-netlist configuration setting of the SoC;
generating second configuration data for the SoC, wherein the second configuration data specifies the change to the non-netlist configuration setting; and
generating updated configuration data for the SoC by merging the second configuration data with the first configuration data leaving the portion of the first configuration data specifying the circuit design unchanged.

12. The system of claim 11, wherein the non-netlist configuration setting includes a configuration setting for a hard circuit block of the SoC.

13. The system of claim 12, wherein the change modifies a state of enablement of the hard circuit block of the SoC as specified by the first configuration data.

14. The system of claim 12, wherein the change modifies subsystem membership of the hard circuit block.

15. The system of claim 11, wherein the non-netlist configuration setting includes a configuration setting for firmware of the SoC.

16. The system of claim 15, wherein the change specifies a modification to error handling within the SoC.

17. The system of claim 15, wherein the change specifies a modification to an inter-processor interrupt channel of the SoC.

18. The system of claim 11, wherein the circuit design is placed and routed and the circuit design for the programmable logic is unaffected by the change to the non-netlist configuration setting of the SoC.

19. The system of claim 11, wherein the hardware processor capable of executing the computer-readable program instructions to perform operations including:
automatically generating firewall circuitry configuration data based on the updated configuration data for the SoC.

20. A computer program product comprising a computer readable storage medium having program instructions embodied therewith, wherein the program instructions are executable by computer hardware to cause the computer hardware to perform operations comprising:
receiving first configuration data for a System-on-Chip (SoC), wherein the SoC has a plurality of hardware systems including programmable logic and the first configuration data includes a portion specifying a circuit design for the programmable logic;
receiving a user input specifying a change to a non-netlist configuration setting of the SoC;
generating second configuration data for the SoC, wherein the second configuration data specifies the change to the non-netlist configuration setting; and
generating updated configuration data for the SoC by merging the second configuration data with the first configuration data leaving the portion of the first configuration data specifying the circuit design unchanged.
